(19) United States
(12) Patent Application Publication
(10) Pub. No.: US 2023/0207635 A1
(43) Pub. Date: Jun. 29, 2023

(54) SEMICONDUCTOR DEVICE

(71) Applicants: DENSO CORPORATION, Kariya-city, Aichi-pref. (JP); TOYOTA JIDOSHA KABUSHIKI KAISHA, Toyota-shi, Aichi-ken (JP); MIRISE Technologies Corporation, Nisshin-shi, Aichi-ken (JP)

(72) Inventors: Atsushi WATANABE, Nisshin-shi, (JP); Tatsuji NAGAOKA, Nisshin-shi, (JP)

(21) Appl. No.: 18/062,289

(22) Filed: Dec. 6, 2022

(30) Foreign Application Priority Data
Dec. 28, 2021 (JP) 2021-214928

(51) Int. Cl. H01L 29/24; H01L 29/872; H01L 23/34

(52) U.S. Cl. CPC H01L 29/24; H01L 29/872; H01L 23/34

(57) ABSTRACT

A semiconductor device includes a semiconductor substrate having a rectangular shape with a side extending in a first direction and another side extending in a second direction. A thermal conductivity in the first direction of the semiconductor substrate is different from a thermal conductivity in the second direction of the semiconductor substrate. The semiconductor substrate is configured to satisfy a mathematical relation of L1/L2=(K1/K2)^{0.5} with an inclusive tolerance range of −5% to +5%, where L1 denotes a length of the semiconductor substrate in the first direction, L2 denotes a length of the semiconductor substrate in the second direction, K1 denotes the thermal conductivity in the first direction of the semiconductor substrate, and K2 denotes the thermal conductivity in the second direction of the semiconductor substrate.

### CROSS REFERENCE TO RELATED APPLICATION

This application is based on Japanese Patent Application No. 2021-214928 filed on Dec. 28, 2021, the disclosure of which is incorporated herein by reference.

### TECHNICAL FIELD

The present disclosure relates to a semiconductor device.

### BACKGROUND

A semiconductor substrate may generate heat during the usage of a semiconductor device. The central portion of the semiconductor substrate tends to have higher temperature than the outer peripheral portion of the semiconductor substrate.

### SUMMARY

The present disclosure describes a semiconductor device including a substrate having a rectangular shape with a side extending in a first direction and another side extending in a second direction.

### BRIEF DESCRIPTION OF DRAWINGS

The above objects, features and advantages of the present disclosure will become more apparent from the following detailed description made with reference to the accompanying drawings. In the drawings:

FIG. 1 is a plan view of a semiconductor chip included in a semiconductor device according to a first embodiment;

FIG. 2 is a longitudinal sectional view of the semiconductor device according to the first embodiment in a [010] direction;

FIG. 3 is a graph showing the relationship between thermal conductivity of β-type gallium oxide and temperature T;

FIG. 4 is a plan view of a semiconductor chip included in a semiconductor device according to a second embodiment; and

FIG. 5 is a longitudinal sectional view of a semiconductor device according to the second embodiment in a [010] direction.

### DETAILED DESCRIPTION

A semiconductor device may be provided such that the density of cells at the central portion of a semiconductor substrate is lower than the outer peripheral portion of the semiconductor substrate. A current flows through the cells of the semiconductor substrate. According to this structure described above, it is possible to suppress a rise in the temperature of the central portion of the semiconductor substrate.

The thermal conductivity of a semiconductor substrate in a semiconductor device may be anisotropic. In such a semiconductor substrate, if the shape of the semiconductor substrate does not match the anisotropic thermal conductivity, the temperature may easily rise at the central portion of the semiconductor substrate.

According to a first aspect of the present disclosure, a semiconductor device includes a semiconductor substrate having a rectangular shape as viewed in a thickness direction of the semiconductor substrate. The rectangular shape has a side extending in a first direction and another side extending in a second direction. A thermal conductivity in the first direction of the semiconductor substrate is different from a thermal conductivity in the second direction of the semiconductor substrate. The semiconductor substrate is configured to satisfy a mathematical relation of L1/L2=(K1/K2)^{0.5} with an inclusive tolerance range of −5% to +5%, where L1 denotes a length of the semiconductor substrate in the first direction, L2 denotes a length of the semiconductor substrate in the second direction, K1 denotes the thermal conductivity in the first direction of the semiconductor substrate, and K2 denotes the thermal conductivity in the second direction of the semiconductor substrate.

In the semiconductor device described above, the thermal resistance of the path from the central portion of the semiconductor substrate to the end portion of the semiconductor substrate in the first direction is substantially identical to the thermal resistance of the path from the central portion of the semiconductor substrate to the end portion of the semiconductor substrate in the second direction. Therefore, it is possible to efficiently dissipate heat from the central portion of the semiconductor substrate in both of the first and second directions, and it is possible to suppress a rise in the temperature of the central portion of the semiconductor substrate.

In a semiconductor device disclosed in the present embodiment, the semiconductor substrate may be made of a p-type gallium oxide-based semiconductor. Additionally, the semiconductor substrate may be made of gallium oxide. Moreover, the semiconductor substrate may be made of p-type gallium oxide. In this case, a first direction described in the present disclosure may be a [010] direction.

In the semiconductor device disclosed in the present disclosure, the semiconductor device may have a top electrode located on a top surface of the semiconductor substrate and a bottom electrode located on a bottom surface of the semiconductor substrate. A current may flow between the top electrode and the bottom electrode through the semiconductor substrate. In this case, a heat sink may be joined to the bottom electrode. The heat sink may have isotropic thermal conductivity. A metal block may be joined to the top electrode. The metal block may have isotropic thermal conduction properties.

The semiconductor device disclosed in the present disclosure may further have a temperature sensing element for sensing the temperature of the semiconductor substrate. The temperature sensing element may be provided at the central portion of the top surface of the semiconductor substrate.

### First Embodiment

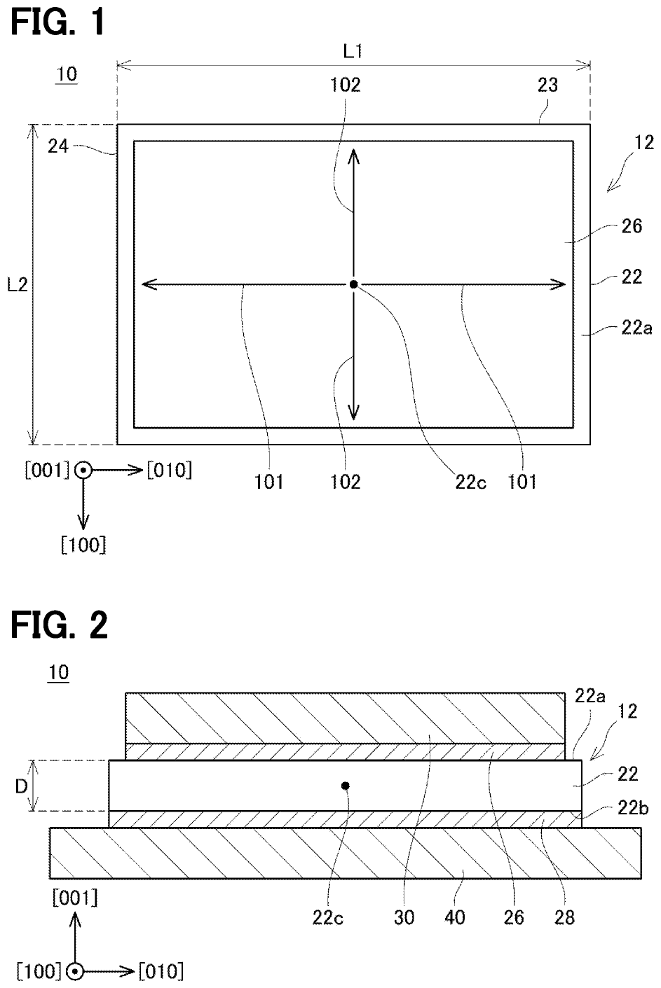

As illustrated in FIGS. 1, 2, a semiconductor device 10 according to a first embodiment includes a semiconductor chip 12, a metal block 30 and a heat sink 40. The metal block 30 is fixed to a top surface of the semiconductor chip 12. The heat sink 40 is fixed to a bottom surface of the semiconductor chip 12. In the first embodiment, the semiconductor chip 12 is a Schottky barrier diode.

The semiconductor chip 12 includes a semiconductor substrate 22, a top electrode 26 and a bottom electrode 28. The semiconductor substrate 22 is made of β-type gallium oxide. A top surface 22a of the semiconductor substrate 22 is made of a (001) plane of the β-type gallium oxide. The thickness direction of the semiconductor substrate 22 is parallel to a [001] direction of the β-type gallium oxide. In the following, the thickness of the semiconductor substrate 22 is referred to as a thickness D. When the semiconductor substrate 22 is viewed in the thickness direction as illustrated in FIG. 1, the semiconductor substrate 22 has an elongated rectangular shape in the lateral direction. The semiconductor substrate 22 has a long side 23 and a short side 24. When the semiconductor substrate 22 is viewed from above, the long side 23 is parallel to the [010] direction of the β-type gallium oxide, and the short side 24 is parallel to a [100] direction of the β-type gallium oxide. In the following, the length of the long side 23, in other words, the length of the semiconductor substrate 22 in the direction is referred to as a length L1; and the length of the short side 24, in other words, the length of the semiconductor substrate 22 in the [100] direction is referred to as a length L2.

The top electrode 26 covers the top surface 22a of the semiconductor substrate 22. The top electrode 26 has a Schottky contact with the semiconductor substrate 22. The bottom electrode 28 covers a bottom surface 22b of the semiconductor substrate 22. The bottom electrode 28 has an ohmic contact with the semiconductor substrate 22. The Schottky barrier diode is formed by the semiconductor substrate 22, the top electrode 26 and the bottom electrode 28. When the potential of the top electrode 26 is higher than the potential of the bottom electrode 28, the current flows from the top electrode 26 to the bottom electrode 28 through the interior of the semiconductor substrate 22. When the potential of the top electrode 26 is lower than the potential of the bottom electrode 28, the current flowing through the semiconductor substrate 22 stops.

The metal block 30 is joined to the top electrode 26 through, for example, solder. Although not shown, the heat sink is joined to the top surface of the metal block 30 through, for example, an insulation layer. The metal block 30 functions as a wiring member for allowing the current to flow through the semiconductor chip 12, and functions as a heat dissipation member for releasing heat from the semiconductor chip 12. The metal block 30 is made of metal such as copper. The metal block 30 has isotropic heat conducting properties. In other words, the thermal conductivity of the metal block 30 is identical in any direction.

The heat sink 40 is joined to the bottom electrode 28 through, for example, the solder. The heat sink 40 functions as a wiring member for allowing the current to flow through the semiconductor chip 12, and functions as a heat dissipation member for releasing heat from the semiconductor chip 12. The heat sink 40 is made of metal such as aluminum. The heat sink 40 has an isotropic thermal conductivity. In other words, the thermal conductivity of the heat sink 40 is identical in any direction.

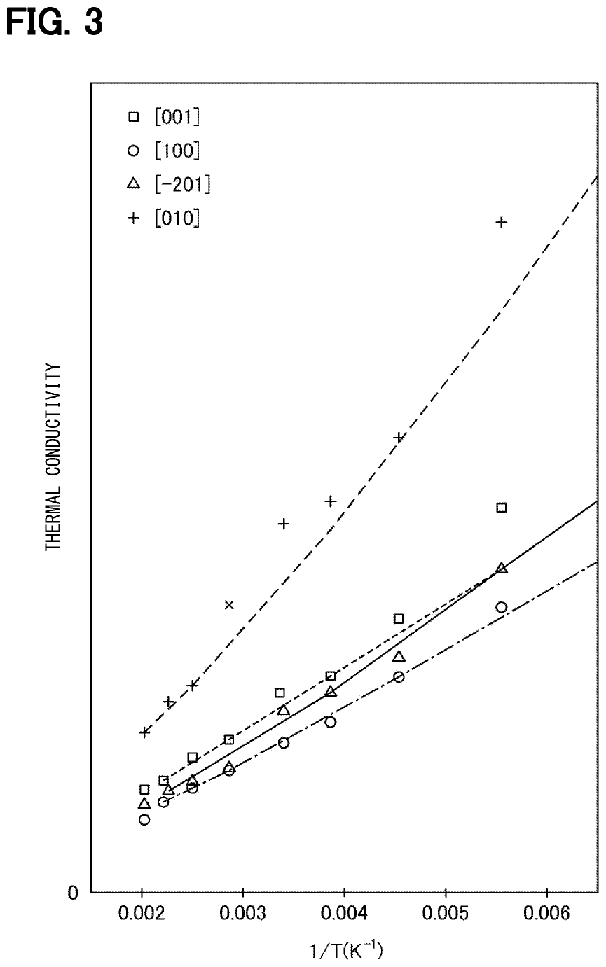

The semiconductor substrate 22 made of the β-type gallium oxide has an anisotropic thermal conductivity. The thermal conductivity of the β-type gallium oxide differs depending on a crystal orientation. FIG. 3 illustrates the relationship between the thermal conductivity of the β-type gallium oxide and the temperature T for each crystal orientation. As shown in FIG. 3, in the β-type gallium oxide, the thermal conductivity in the [010] direction is higher than that in other directions. When the semiconductor substrate 22 is viewed in the thickness direction, the long side 23 is parallel to the [010] direction; and the short side 24 is parallel to the [100] direction. The thermal conductivity K1 of the semiconductor substrate 22 in the direction along the long side 23 is higher than the thermal conductivity K2 of the semiconductor substrate 22 in the direction along the short side 24. For example, the thermal conductivity K1 in the [010] direction at T=150 degrees Celsius (° C.) is 14.4 W/mK, and the thermal conductivity K2 in the [100] direction at T=150° C. is 7.2 W/mK.

The respective lengths L1, L2 of the semiconductor substrate 22 are set to satisfy the following mathematical relation (1) with an inclusive tolerance range of −5% to +5%. It is noted that the following mathematical relation (1) can also be expressed as the mathematical relation of L1/L2=(K1/K2)^{0.5}.

$$\frac{L 1}{L 2} = \sqrt{\frac{K 1}{K 2}} \qquad ( 1 )$$

Additionally, the following mathematical relation (2) indicates the mathematical relation (1) with the inclusive tolerance range of −5% to +5%. It is noted that the following mathematical relation (2) can also be expressed as the mathematical relation of (K1/K2)^{0.5}×0.95 L1/L2 (K1/K2)^{0.5}×1.05.

$$\sqrt{\frac{K 1}{K 2}} \times 0.95 \leq \frac{L 1}{L 2} \leq \sqrt{\frac{K 1}{K 2}} \times 1.05 \qquad ( 2 )$$

When the Schottky barrier diode is turned on and then the current flows through the semiconductor substrate 22, the semiconductor substrate 22 dissipates heat. Since the semiconductor substrate 22 is joined to the metal block 30 and the heat sink 40 over a wide range of the top surface 22a and the bottom surface 22b, the current flows through the semiconductor substrate 22 relatively evenly. Since the semiconductor substrate 22 is joined to the metal block 30 and the heat sink 40 over a wide range of the top surface 22a and the bottom surface 22b, the heat is dissipated substantially evenly at the entire semiconductor substrate 22 through the metal block 30 and the heat sink 40. When the current flows evenly through the semiconductor substrate 22 and the heat is evenly dissipated at the semiconductor substrate 22, a center portion 22c of the semiconductor substrate is at the highest temperature in the semiconductor substrate 22. In other words, the heat dissipated by the semiconductor substrate 22 moves into the semiconductor substrate 22 in a lateral direction, in other words, a direction perpendicular to the thickness direction. The center portion 22c of the semiconductor substrate 22 tends to have higher temperature than the outer peripheral end portion of the semiconductor substrate 22, since the center portion 22c is far from the outer peripheral end portion. The Schottky barrier diode is controlled such that the temperature of the center portion 22c of the semiconductor substrate 22 does not exceed a reference value, in other words, the highest operating temperature, for example, 150° C. set for the Schottky barrier diode. For example, the temperature of the center portion 22c is predicted based on an operating condition of the Schottky barrier diode, and the current value or the electrical conduction time of the Schottky barrier diode is restricted such that the temperature of the center portion 22c does not exceed the reference value. In the semiconductor device 10 according to the first embodiment, since the shape of the semiconductor substrate 22 satisfies the mathematical relation (1), a rise in the temperature of the center portion 22c is suppressed. The following describes the detail of suppressing the rise in the temperature of the center portion 22c. The center portion 22c described in the present disclosure covers the center of the semiconductor substrate 22, and may also be referred to as a central portion of the semiconductor substrate 22.

A heat dissipation path 101 illustrated in FIG. 1 is a heat dissipation path from the center portion 22c to the short side 24, in other words, the outer peripheral end surface of the semiconductor substrate 22, in the [010] direction. A heat dissipation path 102 in FIG. 1 illustrates a heat dissipation path from the center portion 22c to the long side 23, in other words, the outer peripheral end surface of the semiconductor substrate 22, in the [100] direction. The thermal resistance R of a heat dissipation path is defined by the mathematical relation of R=Lr/(S·K). In this mathematical relation, a variable Lr denotes the length of the heat dissipation path; a variable S denotes the cross-sectional area of the heat dissipation path; and a variable K denotes the thermal conductivity of the heat dissipation path. The cross-sectional area S1 of the heat dissipation path 101 is the product of the length L2 and the thickness D. Also, the length Lr1 of the heat dissipation path 101 is a half of the length L1. Therefore, the thermal resistance R1 of the heat dissipation path 101 satisfies the mathematical relationship of R1=Lr1/(S1·K1)=L1/(2·L2·D·K1). The cross-sectional area S2 of the heat dissipation path 102 is the product of the length L1 and the thickness D. The length Lr2 of the heat dissipation path is a half of the length L2. Therefore, the thermal resistance R2 of the heat dissipation path 102 satisfies the mathematical relationship of R2=Lr2/(S2·K2)=L2/(2·L1·D·K2). In a case where the thermal resistance R1 of the heat dissipation path 101 is equal to the thermal resistance R2 of the heat dissipation path 102, the mathematical relationship of L1/(2·L2·D·K1)=L2/(2·L1·D·K2) is satisfied. This mathematical relation is equivalent to the mathematical relation (1). For satisfying the mathematical relation (1), the thermal resistance R1 of the heat dissipation path 101 is equal to the thermal resistance R2 of the heat dissipation path 102.

As described above, the respective lengths L1, L2 of the semiconductor substrate 22 are set to satisfy the mathematical relation (1) with the inclusive tolerance range of −5% to +5%. In the semiconductor substrate 22, the thermal resistance R1 of the heat dissipation path 101 is substantially equal to the thermal resistance R2 of the heat dissipation path 102. When the Schottky barrier diode operates, the heat is substantially dissipated evenly from the center portion 22c through the heat dissipation path 101 and the heat dissipation path 102. The heat is dissipated efficiently by the center portion 22c, and a rise in the temperature of the center portion 22c is suppressed. The semiconductor device 10 according to the first embodiment can continue the operation even under a relatively extreme temperature condition.

As illustrated in FIG. 3, the thermal conductivity changes according to the temperature of the semiconductor substrate. It is possible to adopt thermal conductivities at the temperature within the operating temperature range of the semiconductor device as the thermal conductivities K1, K2 in the mathematical relation (1). For example, thermal conductivities at the highest operating temperature (for example, 150° C.) of the semiconductor device can be adopted as the thermal conductivities K1 and K2.

### Second Embodiment

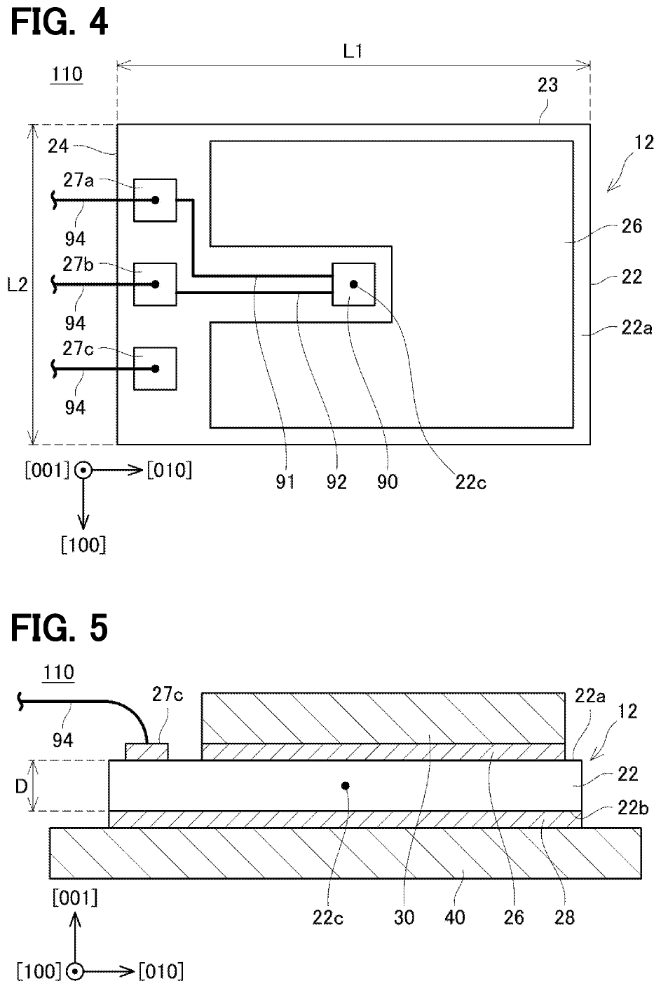

FIGS. 4, 5 respectively illustrate a semiconductor device 110 according to a second embodiment. In FIGS. 4, 5, the reference numerals identical to the ones in the first embodiment are assigned to the parts corresponding to the respective parts of the semiconductor device 10 in the first embodiment. In the semiconductor device 110 according to the second embodiment, the semiconductor chip 12 is a Metal-Oxide-Semiconductor Field-Effect Transistor (MOSFET). That is, a MOSFET structure having, for example, a gate electrode, a gate insulation film, a source layer, a body layer, and a drain layer is formed inside the semiconductor substrate 22. In the second embodiment, the top electrode 26 is a source electrode of the MOSFET; and the bottom electrode 28 is a drain electrode of the MOSFET. The top electrode 26 is connected to the metal block 30, and the bottom electrode 28 is connected to the heat sink 40. In the second embodiment, the metal block 30 is arranged to cover a temperature sensing element 90.

In the second embodiment, the temperature sensing element 90 is provided at the top surface 22a of the semiconductor substrate 22. The temperature sensing element 90 is a p-n diode made of a polysilicon film provided on the top surface 22a of the semiconductor substrate 22. The temperature sensing element 90 is insulated from the semiconductor substrate 22 through the interlayer insulation film (not shown). The top electrode 26 is provided on the top surface 22a to avoid the temperature sensing element 90 and wirings 91, 92 of the temperature sensing element 90. Signal electrodes 27a to 27c are provided on the top surface 22a of the semiconductor substrate 22. The signal electrodes 27a to 27c are arranged next to the top electrode 26. The signal electrodes 27a to 27c are respectively connected to terminals (not shown) through a wire 94.

The signal electrode 27c is connected to the gate electrode (not shown) of the MOSFET. When the MOSFET is used, an electric potential higher than the top electrode 26, in other words, the source electrode is applied to the bottom electrode 28, in other words, the drain electrode. When a predetermined electric potential is applied to the signal electrode 27c, in other words, the gate electrode, the MOSFET is turned on, and the current flows into the semiconductor substrate 22 from the bottom electrode 28 to the top electrode 26. When the electric potential of the signal electrode 27c drops, the MOSFET is turned off and the flow of the current stops.

The signal electrode 27a is connected to the temperature sensing element 90 by the wiring 91. The signal electrode 27b is connected to the temperature sensing element 90 by the wiring 92. It is possible that a constant current flows to the temperature sensing element 90, in other words, a p-n diode through the signal electrodes 27a, 27b. When the temperature of the temperature sensing element 90 changes, a drop in the forward voltage generated by the temperature sensing element 90 changes. Therefore, the temperature of the temperature sensing element 90 can be sensed by sensing a voltage between the signal electrodes 27a and 27b. Since the temperature sensing element 90 is provided at the center of the top surface 22a of the semiconductor substrate 22, it is possible to sense the temperature of the center portion 22c of the semiconductor substrate 22 through the temperature sensing element 90.

In the second embodiment, the semiconductor substrate 22 is made of β-type gallium oxide. In the second embodiment, as similar to the first embodiment, the long side 23 is parallel to the [010] direction; and the short side 24 is parallel to the direction. In the second embodiment, the respective lengths L1, L2 of the semiconductor substrate 22 are set to satisfy the mathematical relation (1) with the inclusive tolerance range of −5% to +5%.

In the second embodiment, the semiconductor substrate 22 dissipates heat during the operation of the MOSFET. The temperature of the center portion 22c of the semiconductor substrate 22 is detected by the temperature sensing element 90 during the operation of the MOSFET. The MOSFET is controlled, such that the temperature of the center portion 22c to be detected by the temperature sensing element 90 does not exceed the reference value, for example, the highest operating temperature defined for the MOSFET. For example, when the temperature detected by the temperature sensing element 90 exceeds the reference value, the current flowing through the MOSFET may be suppressed. For example, when the temperature detected by the temperature sensing element 90 exceeds the reference value, the operation time of the MOSFET may be suppressed. In the second embodiment, as similar to the first embodiment, since the respective lengths L1, L2 of the semiconductor substrate 22 are set to satisfy the mathematical relation (1) with the inclusive tolerance range of −5% to +5%, the heat is efficiently dissipated from the center portion 22c of the semiconductor substrate 22. A rise in the temperature of the center portion 22c of the semiconductor substrate 22 is suppressed, and a rise in the temperature sensed by the temperature sensing element 90 is suppressed. Therefore, the operation of the MOSFET can be continued even under an extreme temperature condition.

In the second embodiment, the location where the temperature is the highest in the semiconductor substrate 22 may be deviated from the center portion 22c according to the layout of the MOSFET in the semiconductor substrate 22. In this case, the location of the temperature sensing element 90 may be shifted from the center portion 22c.

In the first and second embodiments, the direction in which the long side 23 extends is the [010] direction; and the direction in which the short side 24 extends in the [100] direction. As long as the thermal conductivity in the direction in which the long side 23 extends is higher than the thermal conductivity in which the short side 24 extends, each of the direction in which the long side 23 extends and the direction in which the short side 24 extends may be an arbitrary direction.

In the first and second embodiments, the semiconductor substrate 22 may be made of the β-type gallium oxide. However, the semiconductor substrate 22 may be made of other gallium oxide, or the semiconductor substrate 22 may be made of an oxide semiconductor different from gallium oxide. Additionally, the semiconductor substrate 22 may be a semiconductor different from an oxide semiconductor. Various types of material having anisotropic thermal conductivity may be adopted as the material of the semiconductor substrate 22.

The [010] direction described in the embodiment may be, for example, a first direction. The [100] direction described in the embodiment may be, for example, a second direction. The long side 23 described in the embodiment may be, for example, a side extending in the first direction. The short side 24 described in the embodiment may be, for example, a side extending in the second direction.

Although the embodiments have been described in detail above, these are merely examples and do not limit the scope of present disclosure. The techniques described in the present disclosure include various modifications and modifications of the specific examples illustrated above. The technical elements described in the present disclosure or the drawings exhibit technical usefulness alone or in various combinations, and are not limited to the combinations described in the present disclosure at the time of filing. In addition, the techniques illustrated in the present specification or drawings achieve multiple objectives at the same time, and achieving one of the objectives itself has technical usefulness.

What is claimed is:

1. A semiconductor device comprising:
a semiconductor substrate having a rectangular shape as viewed in a thickness direction of the semiconductor substrate, the rectangular shape having a side extending in a first direction and another side extending in a second direction,
wherein a thermal conductivity in the first direction of the semiconductor substrate is different from a thermal conductivity in the second direction of the semiconductor substrate, and
wherein the semiconductor substrate is configured to satisfy a mathematical relation of L1/L2=(K1/K2)^{0.5} with an inclusive tolerance range of −5% to +5%, where
L1 denotes a length of the semiconductor substrate in the first direction,
L2 denotes a length of the semiconductor substrate in the second direction,
K1 denotes the thermal conductivity in the first direction of the semiconductor substrate, and
K2 denotes the thermal conductivity in the second direction of the semiconductor substrate.

2. The semiconductor device according to claim 1,
wherein the semiconductor substrate is made of an oxide semiconductor.

3. The semiconductor device according to claim 1,
wherein the semiconductor substrate is made of gallium oxide.

4. The semiconductor device according to claim 1,
wherein the semiconductor substrate is made of β-type gallium oxide.

5. The semiconductor device according to claim 4,
wherein the first direction is a [010] direction of the β-type gallium oxide.

6. The semiconductor device according to claim 1, further comprising:
a top electrode located on a top surface of the semiconductor substrate; and
a bottom electrode located on a bottom surface of the semiconductor substrate,
wherein the semiconductor substrate is further configured to allow a current flowing between the top electrode and the bottom electrode through the semiconductor substrate.

7. The semiconductor device according to claim 6, further comprising:
a heat sink joined to the bottom electrode.

8. The semiconductor device according to claim 7,
wherein the heat sink has an isotropic thermal conductivity.

9. The semiconductor device according to claim 6, further comprising:
a metal block joined to the top electrode.

10. The semiconductor device according to claim 9,
wherein the metal block has an isotropic thermal conductivity.

11. The semiconductor device according to claim 1, further comprising:
a temperature sensing element configured to sense a temperature of the semiconductor substrate.

12. The semiconductor device according to claim 11,
wherein the temperature sensing element is located at a central portion of a top surface of the semiconductor substrate.
